(19) United States
(12) Patent Application Publication
(10) Pub. No.: US 2024/0393378 A1
(43) Pub. Date: Nov. 28, 2024

(54) SINGLE-POINT SAMPLING OPTIMIZATION METHOD AND SYSTEM FOR FREQUENCY RESPONSE MEASUREMENT

(71) Applicant: XI'AN JIAOTONG UNIVERSITY, Xi'an (CN)

(72) Inventors: Zipeng LIU, Xi'an (CN); Jinjun LIU, Xi'an (CN)

(73) Assignee: XI'AN JIAOTONG UNIVERSITY, Xi'an (CN)

(21) Appl. No.: 18/736,991

(22) Filed: Jun. 7, 2024

Related U.S. Application Data
(63) Continuation of application No. PCT/CN2022/134767, filed on Nov. 28, 2022.

(30) Foreign Application Priority Data
Dec. 9, 2021 (CN) 2021115019142

(51) Int. Cl. G01R 23/18

(52) U.S. Cl. CPC G01R 23/18

(57) ABSTRACT

The present disclosure discloses a single-point sampling optimized method and system for frequency response measurement. The frequency response measurement based on sinusoidal excitation is regarded as frequency domain sampling of system under test, the interpolation error between piecewise linear interpolation model of existing sampling value and the theoretical model of the system under test is estimated, and a single newly added sampling point is placed in the sub-frequency band with maximum interpolation error, so as to achieve steepest descent of an overall interpolation error. The present disclosure does not rely on specific hardware, is directly embedded into existing frequency response analyzer, has high usability, high precision and high stability, and has good data inheritance.

### TECHNICAL FIELD

The present disclosure belongs to the technical field of frequency response measurement, and particularly relates to a single-point sampling optimized method and system for frequency response measurement.

### BACKGROUND

Frequency response measurement method plays a vital role in analysis and debugging of various complex systems. It has two main applications: one is impedance measurement, which measures system impedance or component impedance for facilitating system stability analysis or circuit debugging; and the second is loop analysis, which is mainly used for acquiring a bode plot (i.e., an image of transfer function) of a measured object. For example, performing loop analysis on a switching power supply can conveniently analyze its dynamic performance. In short, frequency response measurement can easily obtain the frequency domain model of the measured object, and is the basis of system design, analysis, and debugging.

At present, there are various frequency response measurement methods in the industry. Although these methods rely on different measurement devices, there are only two classes of excitation signals: compound excitation signal and sinusoidal excitation signal. The compound excitation signal is mainly applicable to linear system, otherwise, spectrum aliasing phenomenon will be caused, thereby reducing measurement precision. However, the sinusoidal excitation signal has good universality for both linear system and nonlinear system, and therefore, the sinusoidal excitation signal still play an irreplaceable role in frequency response measurement.

In the frequency response measurement using sinusoidal excitation, the most conventional method is frequency sweep method, which always uses constant step length in measurement process. At present, commercial frequency response analyzer also mainly uses this method. However, this method is prone to causing problems of measuring speed or measuring precision. For example, if the step length of the measurement is selected too large, the measurement precision cannot be ensured; and if the step length is selected too small, measurement time will be greatly prolonged. Meanwhile, the data inheritance of the frequency sweep method is also poor, which means it cannot reuse existing sampling information well, and which in turn reduces measurement efficiency.

In order to solve the problems of the frequency sweep method, an adaptive frequency injection method is also proposed in the industry, and the position of measurement points may be adaptively allocated according to system curve characteristics of the system under test. Specifically, the adaptive frequency injection method may measure more points in steep portion of system curve and less points in flat portion. Therefore, for the same number of measurement points, measurement precision of the adaptive frequency injection method is higher than that of the frequency sweep method. Meanwhile, this method also ensures the data inheritance, thereby further improving measurement flexibility. However, this method requires user to set absolute error limit value of gain (magnitude value) and phase, is very inconvenient to use, and also has stability problems, and therefore is difficult to apply to practical engineering.

### SUMMARY

The technical problem to be solved by the present disclosure is to provide a single-point sampling optimized method and system for frequency response measurement for deficiencies in the prior art above. The frequency response measurement based on sinusoidal excitation is regarded as frequency domain sampling of system under test, the interpolation error between piecewise linear interpolation model of existing sampling value and theoretical model of the system under test is estimated, and a single newly added sampling point is placed in the sub-frequency band with maximum interpolation error, so as to achieve steepest descent of overall interpolation error. The present disclosure does not rely on specific hardware, only needs to be implemented by means of algorithm, and can be directly embedded into existing frequency response analyzer.

The present disclosure adopts the following technical solutions:
a single-point sampling optimized method for frequency response measurement includes the following steps:
S1, setting the start frequency, the end frequency, and the total number of sampling points;
S2, sampling a plurality of points within a range of the start frequency and the end frequency as initial information;
S3, according to the initial information obtained in step S2, using the trapezoidal rule to estimate the interpolation error of each sub-frequency band divided by known sampling points;
S4, selecting the sub-frequency band with maximum interpolation error from the interpolation errors of all the sub-frequency bands estimated in step S3;
S5, newly adding a sampling point in the sub-frequency band with maximum interpolation error selected in step S4; and
S6, repeating step S3 to step S5 until the number of sampling points reaches the total number of sampling points set in step S1, and ending sampling.

Specifically, in step S1, the total number of sampling points is greater than or equal to 4.

Specifically, in step S2, Nₛ points are sampled at equal intervals within the range of the start frequency and the end frequency as the initial information by using an iterative sampling method.

Specifically, in step S3, using the trapezoidal rule to estimate the interpolation error specifically is:

For a sub-frequency band [fᵢ, fᵢ₊₁, fᵢ₊₂] formed by any three consecutive sampling points, connecting sampling values of the sub-frequency band [fᵢ, fᵢ₊₁, fᵢ₊₂] to form a triangle, the area of the triangle being nearly three times the interpolation error of the sub-frequency band, taking all sampled points one by one as starting points to construct triangles, calculating the area of the corresponding triangle, estimating interpolation errors of all the sub-frequency bands, N sampling points respectively constructing N−2 triangles for gain and phase, and a total of 2N−4 corresponding interpolation errors being provided.

Specifically, in step S4, selecting the sub-frequency band with the maximum interpolation error from the estimated interpolation errors of all the sub-frequency bands specifically is: comparing all 2N−4 interpolation errors of the gain and the phase, selecting the maximum value, and determining the corresponding sub-frequency band [fᵢ, fᵢ₊₁, fᵢ₊₂].

Specifically, in step S5, the newly added sampling point is located in [fᵢ, fᵢ₊₁] of the sub-frequency band selected in step S4, or is located in [fᵢ₊₁, fᵢ₊₂] of the sub-frequency band selected in step S4.

Further, the newly added sampling point is the midpoint of the long interval in [fᵢ, fᵢ₊₁] and [fᵢ₊₁, fᵢ₊₂].

Further, the newly added sampling point is the one-third point or other equal diversion points at the long interval in [fᵢ, fᵢ₊₁] and [fᵢ₊₁, fᵢ₊₂].

Specifically, after step S6 is completed, if a new sampling point needs to be added, a new sampling point number N′ₘ is specified, and the process proceeds to step S3.

Another technical solution of the present disclosure is a single-point sampling optimized system for frequency response measurement, including:
an initial module, configured to sample a plurality of points within a range of the start frequency and the end frequency as initial information;
an estimation module, configured to use, according to the initial information, the trapezoidal rule to estimate the interpolation error of each sub-frequency band divided by known sampling points;
a selecting module, configured to select the sub-frequency band with maximum interpolation error from the estimated interpolation errors of all the sub-frequency bands;
a sample adding module, configured to newly add a sampling point in the selected sub-frequency band with maximum interpolation error; and
a sampling module, configured to repeat the estimation module to the sample adding module until the number of sampling points reaches preset total number of sampling points, and end sampling.

Compared with the prior art, the present disclosure has at least the following beneficial effects:
according to the single-point sampling optimized method for frequency response measurement of the present disclosure, the frequency response measurement based on sinusoidal excitation is regarded as frequency domain sampling of the system under test, by estimating the interpolation error between the piecewise linear interpolation model of the existing sampling value and the theoretical model of the system under test, the single newly added sampling point is placed in the sub-frequency band with maximum interpolation error, so as to achieve steepest descent of the overall interpolation error.

Further, the total number of sampling points Nₘ specifies the number of times of sampling required by sampling target system. At the same time, the total number of sampling points Nₘ has to meet that Nₘ≥4.

Further, some points are first collected as the initial information, then iteration is started, and it is required that Nₛ points are sampled at equal intervals as the initial information, wherein sampling at equal intervals is to sample the system more uniformly, and Nₛ is usually taken as a value of 4. In fact, this does not have strict requirements, and an initial sampling point does not need to strictly meet sampling at equal intervals (the sampling at equal intervals is only optimal); and Nₛ also only needs to meet that Nₛ≥4. Here setting to be 4 means setting a minimum value allowed. This is also why the total number of sampling points Nₘ has to meet that Nₘ≥4.

Further, using the trapezoidal rule to estimate the interpolation error of each sub-frequency band divided by the existing sampling point has advantages that the trapezoidal rule can estimate an interpolation error between existing sampling value and system theoretical model without the system theoretical model. In actual measurement, the system itself is also unknown, and the user can only acquire the sampling value. Therefore, the trapezoid rule is very suitable for practical application. Specifically, the trapezoid rule requires that for the sub-frequency band [fᵢ, fᵢ₊₁, fᵢ₊₂] composed of any three consecutive sampling points, only sampling values corresponding to the sub-frequency band [fᵢ, fᵢ₊₁, fᵢ₊₂] need to be connected to form the triangle, and the area of the triangle is approximately and nearly three times of the interpolation error of the sub-frequency band. It can be seen that, in this process, only the existing sampling value is used to perform estimation without participation of the system theoretical model, but the interpolation error between the existing sampling value and the theoretical model is estimated.

Further, the purpose of selecting the sub-frequency band with the maximum interpolation error from the estimated interpolation errors of all the sub-frequency bands is to find a position where the existing sampling value differs the most from the system theoretical model. Once the sub-frequency band is found, it may be considered that sampling precision of the sub-frequency band is insufficient, and more sampling points need to be added to improve the sampling precision. Specifically, only by comparing the estimated interpolation errors and selecting the maximum value, the corresponding sub-frequency band [fᵢ, fᵢ₊₁, fᵢ₊₂] may be found, and the sub-frequency band is the position where the sampling value differs the most from the system theoretical model.

Further, the newly added sampling point is located in [fᵢ, fᵢ₊₁] of the sub-frequency band selected in step S4, or located in [fᵢ₊₁, fᵢ₊₂] of the sub-frequency band selected in step S4. This is because the selected sub-frequency band is actually composed of three points, namely, [fᵢ, fᵢ₊₁, fᵢ₊₂]. These three points divide the selected sub-frequency band into two smaller sub-frequency bands, namely [fᵢ, fᵢ₊₁] and [fᵢ₊₁, fᵢ₊₂]. Note that these two sub-frequency bands may have different lengths, therefore, a final landing point of the newly added single sampling point should be determined by a relationship between their lengths.

Further, the newly added sampling point is the midpoint at the long interval in [fᵢ, fᵢ₊₁] and [fᵢ₊₁, fᵢ₊₂], because the longer interval implies more unsampled information, such as an implicit resonance peak, and the longer interval naturally should be preferentially sampled. At the same time, the midpoint is selected because the midpoint is a compromise but stable selection, and the midpoint of any frequency band is unique, which can also best ensure data inheritance.

Further, the newly added sampling point is the one-third point or any equal diversion point at the long interval in [for fᵢ₊₁] and [fᵢ₊₁, fᵢ₊₂], the reason of which lies in that the one-third point or the other equal diversion points are also common point selection manners, and these positions are also fixed, thereby ensuring data inheritance.

Further, the user is asked whether a new sampling point needs to be added, and if yes, after the user designates the new sampling point number N′ₘ, step S3 is executed, otherwise, the sampling ends. This step is a flexible implementation of the method, which allows the user to input a new sampling point number N′ₘ again after a round of sampling is finished, and continue sampling on the basis of all the existing sampling values. This is also the data inheritance, that is, for the same system, it may always perform a new sampling task based on the existing sampling value, and the result of firstly sampling Nₘ points and then sampling N′ₘ points is completely consistent with the result of directly sampling Nₘ+N′ₘ points from the beginning. Therefore, the user may always add new sampling points continuously to meet the requirement for precision.

In conclusion, the present invention does not require the system theoretical model, directly uses the trapezoidal rule to estimate the interpolation error between the sampling value and the system theoretical model by using the existing sampling value, and places the newly added sampling point in the sub-frequency band with maximum interpolation error, thereby achieving steepest descent of the overall interpolation error. The present disclosure does not rely on specific hardware, only needs to be implemented by means of algorithm, may be directly embedded into existing frequency response analyzer, has high usability, high precision and high stability, and has good data inheritance.

The technical solutions of the present disclosure are further described in detail below through accompanying drawings and embodiments.

### BRIEF DESCRIPTION OF DRAWINGS

FIG. 1 is a bode plot of a transfer function of a to-be-tested system in numerical testing;

FIG. 2 is a flow diagram of implementing a single-point sample optimized method in the present disclosure;

FIG. 3 is a schematic diagram of constructing triangles according to existing sampling information in the present disclosure;

FIG. 4 is an example diagram of sampling process of single-point sampling optimized method in the present disclosure; and

FIGS. 5a and 5b is a comparison diagram of sampling errors among three frequency response measurement methods based on sinusoidal excitation in numerical testing.

### DETAILED DESCRIPTION OF THE EMBODIMENTS

Technical solutions in embodiments of the present disclosure will be described below clearly and completely with reference to accompanying drawings in the embodiments of the present disclosure. Obviously, the described embodiments are part of the embodiments of the present disclosure, but not all the embodiments. On the basis of the embodiments in the present disclosure, all other embodiments obtained by those ordinarily skilled in the art without creative efforts fall within the protection scope of the present disclosure.

The present disclosure provides a single-point sampling optimized method for frequency response measurement, the frequency response measurement based on sinusoidal excitation is regarded as frequency domain sampling of system under test, by estimating interpolation error between piecewise linear interpolation model of existing sampling value and theoretical model of the system under test, a single newly added sampling point is placed in the sub-frequency band with maximum interpolation error, so as to achieve steepest descent of an overall interpolation error. The present disclosure does not rely on specific hardware, only needs to be implemented by means of algorithm, may be directly embedded into existing frequency response analyzer, has high usability, high precision and high stability, and has good data inheritance, thereby greatly improving practicability of frequency response measurement method based on sinusoidal excitation.

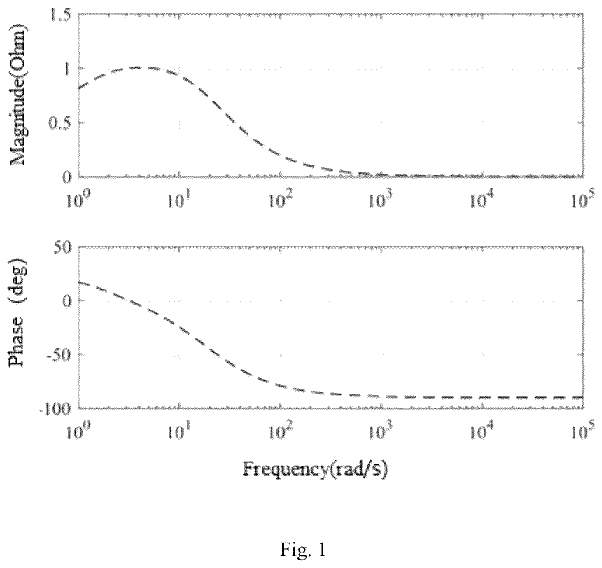

Please refer to FIG. 1, according to the present disclosure, the start frequency, the end frequency, and the total number of sampling points for sampling are first set by user; a plurality of points are sampled at equal intervals within a range of the start frequency and the end frequency as initial information; the interpolation error of each sub-frequency band is estimated based on existing sampling information; the sub-frequency band with maximum interpolation error is selected; a sampling point is newly added at appropriate position within the sub-frequency band; continuous circulation is performed until the number of sampling points reaches the total number set by the user; and the user is asked if he/she needs to add new sampling points, if yes, the interpolation error of each sub-frequency band is re-estimated after the user specifies the number of new sampling points, otherwise, the sampling ends.

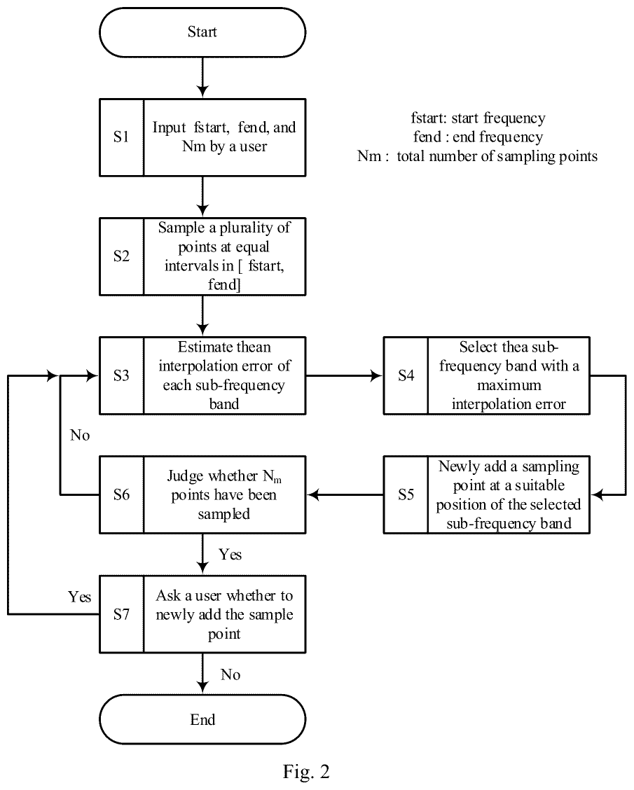

Please refer to FIG. 2, a single-point sampling optimized method for frequency response measurement of the present disclosure includes the following steps:

S1, user sets the start frequency fₛₜₐᵣₜ, the end frequency f_{end}, and the total number of sampling points Nₘ for sampling.

The start frequency fₛₜₐᵣₜ, the end frequency f_{end}, and the total number of sampling points Nₘ for sampling are set by the user. These three parameters are three preset parameters that a sampling task must have. The start frequency fₛₜₐᵣₜ and the end frequency f_{end} specify a frequency range of sampling, and the total number of sampling points Nₘ must meet that Nₘ≥4.

S2, Nₛ points are sampled within a range of the start frequency fₛₜₐᵣₜ and the end frequency f_{end} as initial information.

This method is essentially an iterative sampling method, that is, each sampling point is a global optimum point calculated on the basis of sampled information.

S3, according to existing sampling information, the interpolation error eᵢ of each sub-frequency band divided by known sampling points are estimated, i=1, 2, . . . 2N−4, wherein N represents the number of sampled points.

This method uses the trapezoidal rule when estimating the interpolation error, that is, after sampling values of a sub-frequency band [fᵢ, fᵢ₊₁, fᵢ₊₂] formed by any three consecutive sampling points are connected to form a triangle, the area of the triangle is approximately and nearly three times of the interpolation error of the sub-frequency band. Therefore, if all the sampled points are taken as starting points one by one to construct triangles, and the area of the corresponding triangle is calculated, the interpolation errors of all the sub-frequency bands may be estimated. Because there are a total of N sampling points, N−2 triangles are constructed for the gain (magnitude values) and the phase respectively, so that there are a total of 2N−4 corresponding interpolation errors. Since calculated values of the area of these triangles may be positive or negative, all the calculated values should be taken as absolute values to achieve a fair comparison in numerical values. At the same time, since the triangles of the gain (magnitude values) and the phase are placed together for comparison, it is also necessary to take relative values for the areas of these triangles. That is, the relative values are taken respectively with respect to average values of the areas of the triangles in the gain (magnitude values) and the phase, so as to achieve fair comparison of orders of magnitude.

It is worth noting that although this method uses the trapezoidal rule when estimating the interpolation error, other similar interpolation error estimation methods should also be covered in the scope of protection.

S4, the sub-frequency band [fᵢ, fᵢ₊₁, fᵢ₊₂] with maximum interpolation error is selected, and its corresponding error is max (eᵢ).

All 2N−4 interpolation errors of the gain (magnitude values) and the phase are compared together to select the maximum value thereof and find the corresponding sub-frequency band [fᵢ, fᵢ₊₁, fᵢ₊₂]. Apparently, the error of the sub-frequency band is max (eᵢ). It is worth noting that there are currently many algorithms for selecting the maximum value, and this method is not limited to a certain specific algorithm when selecting the maximum error.

S5, a sampling point is newly added at appropriate position within the sub-frequency band, specifically, the point may be located in [fᵢ, fᵢ₊₁] or may be located in [fᵢ₊₁, fᵢ₊₂].

In fact, an optimal position for this point is the midpoint at the longer interval in [fᵢ, fᵢ₊₁] and [fᵢ₊₁, fᵢ₊₂], that is, if fᵢ₊₁−fᵢ≥fᵢ₊₂−fᵢ₊₁, the newly added point should be the midpoint of [fᵢ, fᵢ₊₁], otherwise it should be the midpoint of [fᵢ₊₁, fᵢ₊₂]. This is because a longer frequency band contains more implicit information, such as a resonant peak that has not yet been sampled. Of course, this point may not necessarily be strictly located at the longer interval, and may also be fixed to always be in [fᵢ, fᵢ₊₁], or always in [fᵢ₊₁, fᵢ₊₂]. At the same time, this point may not necessarily be strictly set as the midpoint, but may also be other fixed positions, such as a one-third point or a quarter point. Selecting the midpoint of the longer interval here is almost the optimal choice.

S6, step S3 to step S5 are continuously circulated until the number of sampling points reaches the total number set by the user, that is, when N==Nₘ, the current round of sampling ends.

N is a count of the number of sampled points. For each new point sampled, N=N+1 is set, and whether N==Nₘ has been met is judged. If the condition has not been met yet, the process proceeds to step S3, and new points are continued to be sampled; and if the condition has already been met, the current round of sampling ends.

S7, if the user needs to add the new sampling points, after the user specifies the new sampling point number N′ₘ, the process proceeds to step S3. If the user does not need to add the new sampling points, the sampling ends.

In another embodiment of the present disclosure, a single-point sampling optimized system for frequency response measurement is provided. The system can be used for implementing the above single-point sampling optimized method for frequency response measurement. Specifically, the single-point sampling optimized system for frequency response measurement includes an initial module, an estimation module, a selecting module, a sample adding module, and a sampling module.

The initial module is configured to sample a plurality of points within a range of the start frequency and the end frequency as initial information;
the estimation module is configured to use, according to the initial information, the trapezoidal rule to estimate the interpolation error of each sub-frequency band divided by known sampling points;
the selecting module is configured to select the sub-frequency band with maximum interpolation error from the estimated interpolation errors of all the sub-frequency bands;
the sample adding module is configured to newly add a sampling point in the selected sub-frequency band with the maximum interpolation error; and
the sampling module is configured to repeat the estimation module to the sample adding module until the number of sampling points reaches preset total number of sampling points, and end sampling.

In another embodiment of the present disclosure, a terminal device is provided. The terminal device includes a processor and a memory, the memory is configured to store a computer program, the computer program includes program instructions, and the processor is used for executing the program instructions stored in the computer storage medium. The processor may be a central processing unit (CPU), and may further be other general-purpose processors, digital signal processors (DSPs), application specific integrated circuits (ASICs), field-programmable gate arrays (FPGAs) or other programmable logic devices, discrete gate or transistor logic devices, discrete hardware components, etc., the processor is a computing core and control core of a terminal, and is suitable for implementing one or more instructions, specifically suitable for loading and executing one or more instructions to implement corresponding method flows or functions. The processor described in the embodiment of the present disclosure may be used for an operation of a single-point sampling optimized method for frequency response measurement, including:
setting the start frequency, the end frequency, and the total number of sampling points for sampling; sampling a plurality of points within a range of the start frequency and the end frequency as initial information; according to the initial information, using the trapezoidal rule to estimate the interpolation error of each sub-frequency band divided by known sampling points; selecting the sub-frequency band with maximum interpolation error from the estimated interpolation errors of all the sub-frequency bands; newly adding a sampling point within the selected sub-frequency band with maximum interpolation error; and repeating the above steps until the number of sampling points reaches the total number of sampling points, and ending sampling.

In another embodiment of the present disclosure, the present disclosure further provides a storage medium, specifically a computer readable storage medium (Memory), and the computer readable storage medium is a memory device in a terminal device for storing programs and data. It may be understood that the computer readable storage medium here may include both a built-in storage medium in the terminal device and an extended storage medium supported by the terminal device. The computer readable storage medium provides a storage space, and the storage space stores an operating system of a terminal. Moreover, the storage space further stores one or more instructions suitable for being loaded and executed by a processor, and these instructions may be one or more computer programs (including program codes). It needs to be noted that the computer readable storage medium here may be a high-speed RAM memory or a non-volatile memory, such as at least one disk storage.

The one or more instructions stored in the computer readable storage medium may be loaded and executed by the processor to achieve corresponding steps of the relevant single-point sampling optimized method for frequency response measurement in the above embodiments. One or more instructions in the computer readable storage medium are loaded by the processor to execute the following steps:
setting the start frequency, the end frequency, and the total number of sampling points for sampling; sampling a plurality of points within a range of the start frequency and the end frequency as initial information; according to the initial information, using the trapezoidal rule to estimate the interpolation error of each sub-frequency band divided by known sampling points; selecting the sub-frequency band with maximum interpolation error from the estimated interpolation errors of all the sub-frequency bands; newly adding a sampling point within the selected sub-frequency band with the maximum interpolation error; and repeating the above steps until the number of sampling points reaches the total number of sampling points, and ending sampling.

In order to make objectives, technical solutions and advantages of the embodiments of the present disclosure clearer, the technical solutions in the embodiments of the present disclosure will be described below clearly and completely with reference to accompanying drawings in the embodiments of the present disclosure. Apparently, the described embodiments are part of the embodiments of the present disclosure, but not all the embodiments. The components of the embodiments of the present disclosure, as described and illustrated in the accompanying drawings here, may be usually arranged and designed through various different configurations. Therefore, the following detailed description of the embodiments of the present disclosure provided in the accompanying drawings is not intended to limit the scope of protection of the present disclosure, but merely represents selected embodiments of the present disclosure. On the basis of the embodiments in the present disclosure, all other embodiments obtained by those ordinarily skilled in the art without creative efforts fall within the scope of protection of the present disclosure.

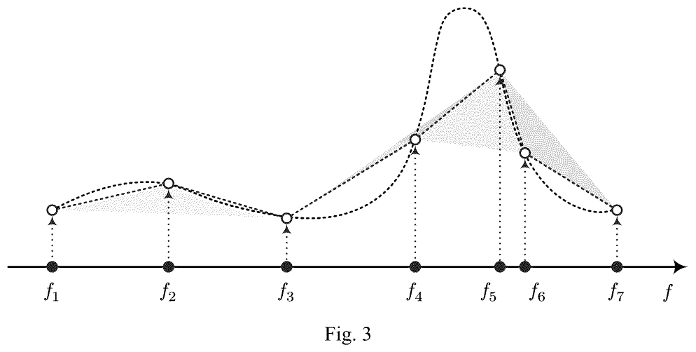

When using this method, the interpolation error of all the sub-frequency bands will be estimated based on the trapezoidal rule, that is, for all the sampled points, triangles are constructed starting from each point, and the area of the corresponding triangle is calculated, as shown in FIG. 3.

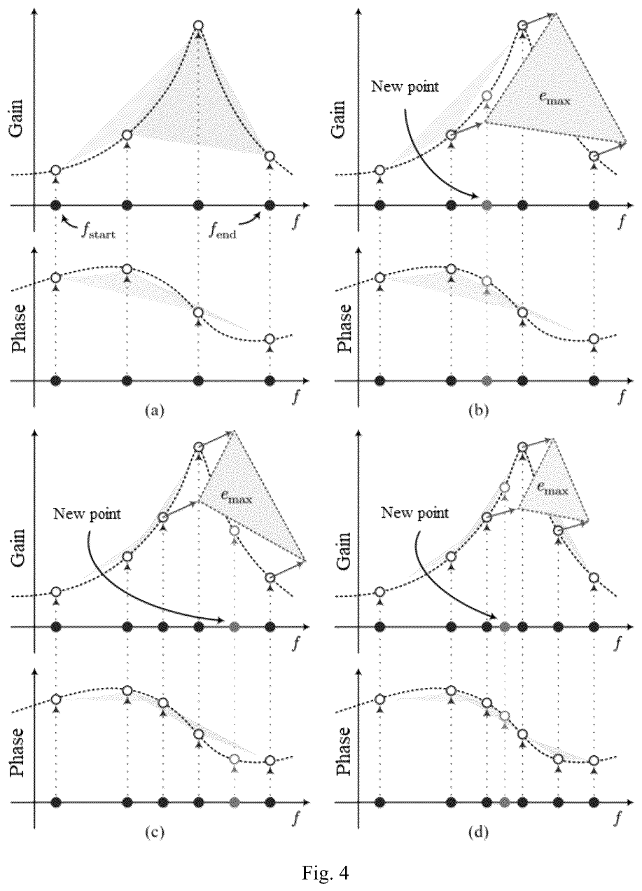

Afterwards, the one with maximum relative value is selected from all the estimated errors, the corresponding sub-frequency band is found, and then the sampling point is newly added in the sub-frequency band. This sampling process is as shown in FIG. 4.

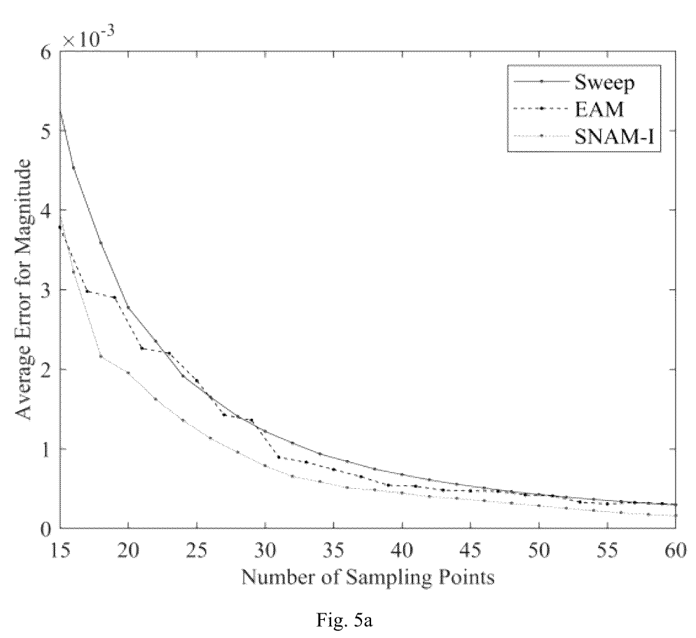

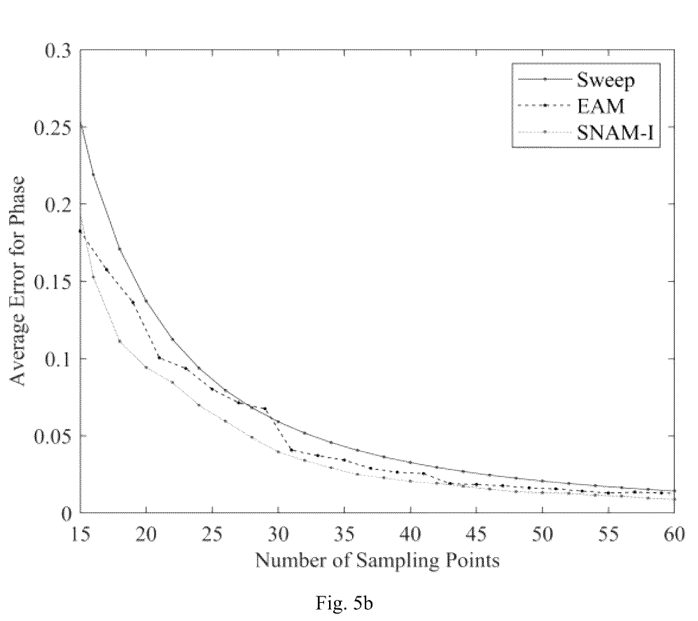

When performing numerical testing on the system shown in FIG. 1, the frequency sweep method, the adaptive frequency injection method, and the present disclosure are selected jointly for testing. From FIGS. 5a and 5b, it can be seen that as the number of sampling points constantly increases, the overall error of the three frequency response measurement methods decreases, and the present disclosure always has the lowest error, which proves effectiveness of the method of the present disclosure.

In summary, the single-point sampling optimized method and system for frequency response measurement of the present disclosure optimizes the position of each sampling point in frequency response measurement and makes distribution of sampling point positions more reasonable. The frequency response measurement based on sinusoidal excitation is regarded as frequency domain sampling of the system under test, by estimating the interpolation error between piecewise linear interpolation model of the existing sampling value and the theoretical model of the system under test, the single newly added sampling point is placed in the sub-frequency band with maximum interpolation error, so as to achieve steepest descent of the overall interpolation error. The present disclosure mainly has the following advantages:
firstly, the usability is high, the method only requires the user to specify the start frequency, the end frequency and the total number of sampling points for sampling, and does not need to specify any other empirical parameters;
secondly, the precision is high, the method estimates the interpolation error of each sub-frequency band based on the trapezoidal rule and always adds the new sampling point in the sub-frequency band with the maximum interpolation error, therefore, as the sampling points increase, the overall interpolation error decreases at an almost fastest speed;
thirdly, stability is high, the sampling mechanism of this method ensures that more sampling points always have higher sampling precision, and therefore there is no problem of the stability; and
fourthly, the data inheritance is good, and the method may always perform a new sampling task based on all sampled information, thereby improving the sampling efficiency and embodying the good data inheritance.

Those skilled in the art should understand that the embodiments of the present application may be provided as methods, systems or computer program products. Therefore, the present application can adopt forms of full hardware embodiments, full software embodiments, or embodiments combining software and hardware aspects. Moreover, the present application may adopt a form of the computer program products implemented on one or more computer available storage mediums (including but not limited to a disk memory, a CD-ROM, an optical memory and the like) containing computer available program codes.

The present application is described with reference to flow diagrams and/or block diagrams of the methods, the devices (systems), and computer program products according to the embodiments of the present application. It should be understood that each flow and/or block in the flow diagrams and/or the block diagrams and combinations of the flows and/or the blocks in the flow diagrams and/or the block diagrams can be implemented by computer program instructions. These computer program instructions may be provided to a processor of a general-purpose computer, a special-purpose computer, an embedded processing machine or other programmable data processing devices to generate a machine, such that the instructions, when executed by the processor of the computer or other programmable data processing devices, generate an apparatus for implementing functions specified in one or more flows in the flow diagrams and/or one or more blocks in the block diagrams.

These computer program instructions may also be stored in a computer readable memory which can guide the computer or other programmable data processing devices to work in a specific mode, thus the instructions stored in the computer readable memory generates an article of manufacture that includes a commander apparatus that implement the functions specified in one or more flows in the flow diagrams and/or one or more blocks in the block diagrams.

These computer program instructions may also be loaded to the computer or other programmable data processing devices, so that a series of operating steps are executed on the computer or other programmable devices to generate computer-implemented processing, such that the instructions executed on the computer or other programmable devices provide steps for implementing the functions specified in one or more flows in the flow diagrams and/or one or more blocks in the block diagrams.

The above content is only for explaining the technical concept of the present disclosure and cannot limit the scope of protection of the present disclosure. Any modifications made based on the technical solutions according to the technical concept proposed in the present disclosure shall fall within the scope of protection of the claims of the present disclosure.

What is claimed is:

1. A single-point sampling optimized method for frequency response measurement, comprising the following steps:
S1, setting the start frequency, the end frequency, and the total number of sampling points for sampling;
S2, sampling a plurality of points within a range of the start frequency and the end frequency as initial information;
S3, according to the initial information obtained in step S2, using the trapezoidal rule to estimate interpolation error of each sub-frequency band divided by known sampling points, using the trapezoidal rule to estimate the interpolation error specifically being:
for a sub-frequency band [fᵢ, fᵢ₊₁, fᵢ₊₂] formed by any three consecutive sampling points, connecting sampling values of the sub-frequency band [fᵢ, fᵢ₊₁, fᵢ₊₂] to form a triangle, an area of the triangle being nearly three times the interpolation error of the sub-frequency band, taking all sampled points one by one as starting points to construct triangles, calculating the corresponding area of the triangle, estimating interpolation errors of all the sub-frequency bands, N sampling points respectively constructing N−2 triangles for gain and phase, and a total of 2N−4 corresponding interpolation errors being provided;
S4, selecting the sub-frequency band with maximum interpolation error from the interpolation errors of all the sub-frequency bands estimated in step S3;
S5, newly adding a sampling point in the sub-frequency band with maximum interpolation error selected in step S4; and
S6, repeating step S3 to step S5 until the number of sampling points reaches the total number of sampling points set in step S1, and ending sampling.

2. The single-point sampling optimized method for frequency response measurement according to claim 1, wherein in step S1, the total number of sampling points is greater than or equal to 4.

3. The single-point sampling optimized method for frequency response measurement according to claim 1, wherein in step S2, Nₛ points are sampled at equal intervals within the range of the start frequency and the end frequency as the initial information by using an iterative sampling method.

4. The single-point sampling optimized method for frequency response measurement according to claim 1, wherein in step S4, selecting the sub-frequency band with maximum interpolation error from the estimated interpolation errors of all the sub-frequency bands specifically is: comparing all 2N−4 interpolation errors of the gain and the phase, selecting the maximum value, and determining the corresponding sub-frequency band [fᵢ, fᵢ₊₁, fᵢ₊₂].

5. The single-point sampling optimized method for frequency response measurement according to claim 1, wherein in step S5, the newly added sampling point is located in [fᵢ, fᵢ₊₁] of the sub-frequency band selected in step S4, or is located in [fᵢ₊₁, fᵢ₊₂] of the sub-frequency band selected in step S4.

6. The single-point sampling optimized method for frequency response measurement according to claim 5, wherein the newly added sampling point is the midpoint of the long interval in [fᵢ, fᵢ₊₁] and [fᵢ₊₁, fᵢ₊₂].

7. The single-point sampling optimized method for frequency response measurement according to claim 5, wherein the newly added sampling point is the one-third point or any equal diversion point at the long interval in [fᵢ, fᵢ₊₁] and [fᵢ₊₁, fᵢ₊₂].

8. The single-point sampling optimized method for frequency response measurement according to claim 1, wherein after step S6 is completed, if a new sampling point needs to be added, a new sampling point number N′ₘ is specified, and the process proceeds to step S3.

9. A single-point sampling optimized system for frequency response measurement, comprising:
an initial module, configured to sample a plurality of points within a range of the start frequency and the end frequency as initial information;
an estimation module, configured to use, according to the initial information, the trapezoidal rule to estimate the interpolation error of each sub-frequency band divided by known sampling points, using the trapezoidal rule to estimate the interpolation error being specifically:
for a sub-frequency band [fᵢ, fᵢ₊₁, fᵢ₊₂] formed by any three consecutive sampling points, connecting sampling values of the sub-frequency band [fᵢ, fᵢ₊₁, fᵢ₊₂] to form a triangle, the area of the triangle being nearly three times the interpolation error of the sub-frequency band, taking all sampled points one by one as starting points to construct triangles, calculating the corresponding area of the triangle, estimating interpolation errors of all the sub-frequency bands, N sampling points respectively constructing N−2 triangles for gain and phase, and a total of 2N−4 corresponding interpolation errors being provided;
a selecting module, configured to select the sub-frequency band with maximum interpolation error from the estimated interpolation errors of all the sub-frequency bands;
a sample adding module, configured to newly add a sampling point in the selected sub-frequency band with maximum interpolation error; and
a sampling module, configured to repeat the estimation module to the sample adding module until the number of sampling points reaches preset total number of sampling points, and end sampling.
